(19) United States
(12) Patent Application Publication
(10) Pub. No.: US 2013/0105852 A1
(43) Pub. Date: May 2, 2013

(54) PACKAGE STRUCTURE AND MANUFACTURING METHOD FOR THE SAME

(71) Applicants: Wei-Cheng LOU, Yangmei City (TW); Fong-Yee JAN, Yangmei City (TW); Chung-I CHIANG, Yangmei City (TW)

(72) Inventors: Wei-Cheng LOU, Yangmei City (TW); Fong-Yee JAN, Yangmei City (TW); Chung-I CHIANG, Yangmei City (TW)

(73) Assignee: WALSIN LIHWA CORPORATION, Yangmei City (TW)

(21) Appl. No.: 13/360,950

(22) Filed: Jan. 30, 2012

(30) Foreign Application Priority Data
Nov. 1, 2011 (TW) 100139705

(51) Int. Cl. H01L 33/62; H01L 21/50

(52) U.S. Cl. 257/99; 438/118; 257/E33.062; 257/E21.499

(57) ABSTRACT

A package structure and a manufacturing method for the same are provided. The package structure includes a chip, a substrate and at least one adhesive layer. The chip has at least one electrode portion. The substrate has at least one circuit portion. The adhesive layer is disposed between the electrode portion and the circuit portion to form an electrical connection therebetween. The adhesive layer is a material, which comprises a metal compound, with a Negative Coefficient of Thermal Expansion (Negative CTE). Because of the material with a Negative CTE, the alignment shift can be avoided after the chip and the substrate are adhered together.

### This application claims the benefit from the priority to Taiwan Patent Application No. 100139705 filed on Nov. 1, 2011, the disclosure of which is incorporated by reference herein in its entirety.

### CROSS-REFERENCES TO RELATED APPLICATIONS

Not applicable.

### BACKGROUND OF THE INVENTION

1. Field of the Invention

The embodiments of the present invention provide a package structure and a manufacturing method for the same. More particularly, the embodiments of the present invention provide a package structure comprising a material with a negative coefficient of thermal expansion (negative CTE) and a manufacturing method for the package structure.

2. Descriptions of the Related Art

As semiconductor manufacturing processes have become increasingly sophisticated and advanced over recent years, various kinds of high-performance electronic products have been developed in succession. Chips are known as the most important component in these electronic products, so the quality and performances of the chips have received much attention in the art. Generally, the die bonding process has the most prominent influence on the performances of the chips in the chip packaging. In the die bonding process, an adhesive material is used to electrically connect the electrodes or bumps of a chip to a circuit on a substrate so that electronic signals can be transmitted between the chip and the external circuit on the substrate. Conventional adhesive materials mainly fall into two categories: organic polymer conductive adhesives and inorganic metal alloy solders.

However, both the conductive adhesives and the alloy solders used for adhering the chip to the substrate have properties of thermal expansion and contraction. Therefore, when the temperature rises, the adhesive material will expand in volume to result in pores inside the adhesive material. This not only makes it difficult to reduce the volume of the package by reducing the distance between the chip and the substrate, but may also enlarge the distance due to the presence of the pores, thus, causing alignment errors during the adhesion of the chip. Moreover, when a metal solder is used in the chip adhering process, the high temperature of the melt alloy solder tends to cause damage to the insides of the chip and the substrate. The high temperature may also cause stress changes in the chip and the substrate, which is unfavorable for subsequent manufacturing processes. Therefore, the soldering temperature and the soldering time must be controlled.

Accordingly, it is important to provide a solution that can avoid positional errors between the chip and substrate of a package due to thermal expansion and contraction in the volume of the adhesive material.

### SUMMARY OF THE INVENTION

An objective of the embodiments of the present invention is to provide a package structure and a manufacturing method for the same. Because materials with a negative coefficient of thermal expansion (negative CTE) are used for the electrical connection between the chip and the substrate in the package structure, alignment errors between the chip and the substrate that would affect signal transmission therebetween can be avoided after curing the bonding material.

To achieve the aforesaid objective, the embodiments of the present invention provide a package structure, which comprises a chip, a substrate and at least one adhesive layer. The chip has at least one electrode portion; the substrate has at least one circuit portion. The adhesive layer is disposed between the at least one electrode portion and the at least one circuit portion to form an electrical connection therebetween. The adhesive layer is a material, comprising a metal compound, with a negative CTE. Thereby, the alignment shifting that occurs between the chip and the substrate can be avoided.

To achieve the aforesaid objective, the embodiments of the present invention further provide a manufacturing method for the aforesaid package structure. The method comprises the following steps: forming at least one electrode portion on a die to form a chip; forming at least one circuit portion on a base to form a substrate; and disposing at least one adhesive layer between the at least one electrode portion and the at least one circuit portion to form an electrical connection between the chip and the substrate. The adhesive layer is a material, comprising a metal compound, with a negative CTE.

The detailed technology and preferred embodiments implemented for the subject invention are described in the following paragraphs accompanying the appended drawings for people skilled in this field to well appreciate the features of the claimed invention.

### BRIEF DESCRIPTION OF THE DRAWINGS

FIG. 1 is a schematic view of the preferred embodiment of a package structure according to the embodiment of the present invention;

FIG. 2 is a flowchart diagram of the manufacturing method for the package structure according to the embodiment of the present invention; and

FIG. 3 is another flowchart diagram of the manufacturing method for the package structure according to the embodiment of the present invention.

### DESCRIPTION OF THE PREFERRED EMBODIMENT

In the following description, the present invention will be explained with reference to embodiments thereof. The embodiments of the present invention provide a package structure and a manufacturing method for the same. It should be appreciated that the description of these embodiments is only for the purpose of illustration rather than to limit the present invention. In the following embodiments and attached drawings, elements unrelated to the embodiments of the present invention are omitted from depiction; and dimensional relationships among individual elements in the attached drawings are illustrated only for ease of understanding, but not to limit the actual scale.

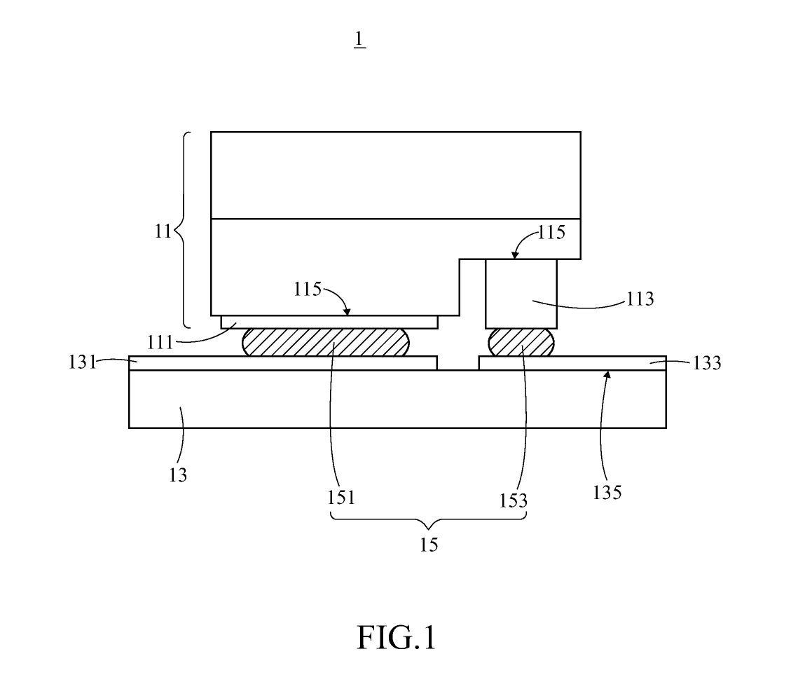

FIG. 1 illustrates a schematic view of the preferred embodiment of a package structure 1 according to the present invention. The package structure 1 comprises a chip 11, a substrate 13 and an adhesive layer 15, which will be detailed in sequence hereinbelow.

In this embodiment, the chip 11 is a light emitting diode (LED) chip, and has a first electrode portion 111 and a second electrode portion 113 formed on the lower surface 115 of the chip 11 respectively. In this embodiment, the first electrode portion 111 and the second electrode portion 113 have different areas and are an anode and a cathode respectively. Furthermore, the package structure of the embodiment of the present invention is not limited to the light emitting diode chip package, but may also be suitable for other kinds of chip packages (e.g., a memory chip, a microchip, an analogy chip and a logical chip). Moreover, the number of electrode portions is not limited to what is illustrated above, and the electrode portions may also be replaced by bumps.

The upper surface 135 of the substrate 13 has a circuit layout, which comprises a first circuit portion 131 and a second circuit portion 133 corresponding to the first electrode portion 111 and the second electrode portion 113 of the chip 11 respectively. In detail, the chip 11 is stacked along the vertical direction of the upper surface 135 of the substrate 13. The area of the substrate 13 is greater than that of the chip 11 so that the chip 11 can be disposed completely within the range of the upper surface 135 of the substrate 13. The substrate 13 may be a component capable of transmitting electric energy such as a circuit board or a chip. In this embodiment, the first circuit portion 131 and the second circuit portion 133 have different areas.

The adhesive layer 15 has a first adhesive layer 151 and a second adhesive layer 153. The first adhesive layer 151 is disposed between the first electrode portion 111 and the first circuit portion 131 to form an electrical connection therebetween. The second adhesive layer 153 is disposed between the second electrode portion 113 and the second circuit portion 133 to form an electrical connection therebetween. Thus, the chip 11 can be electrically connected to the substrate 13 for signal transmission therebetween.

In this embodiment, the first adhesive layer 151 and the second adhesive layer 153 have different thermal expansion coefficients. By virtue of the properties of the materials with different thermal expansion coefficients, shifting levels between the first electrode portion 111 and the first circuit portion 131 and between the second electrode portion 113 and the second circuit portion 133, which has different area from the first electrode portion 111, can be adjusted by the first adhesive layer 151 and the second adhesive layer 153 respectively so that the chip 11 can be adhered to the substrate 13 tightly without moving with respect to the substrate 13 easily.

The first adhesive layer 151 and the second adhesive layer 153 of the embodiment of the present invention are each materials with a negative coefficient of thermal expansion (negative CTE); and in detail, the working temperature of the material with the negative coefficient of thermal expansion is−273 to 800. After the chip 11 is stacked above the substrate 13, the first adhesive layer 151 and the second adhesive layer 153 with negative coefficients of thermal expansion are heated to reduce the volumes thereof.

The materials with the negative coefficients of thermal expansion adopted by the first adhesive layer 151 and the second adhesive layer 153 each comprise a metal compound material. The metal compound material in this embodiment comprises (but is not limited to) ZrW₂O₈, PbTiO₃, BaTiO₃, ZrV₂O₇, TaVO₅, LiAlSiO₄, AgI or a combination thereof.

In addition to the materials with negative coefficients of thermal expansion described above, people skilled in the art may proceed with another embodiment of the present invention in which the aforesaid metal compound material is doped in a glass-ceramic, a resin, a ceramic or a combination thereof. Similarly, by virtue of the properties of the materials with negative coefficients of thermal expansion, the problems of sliding and misalignment caused by a high temperature between the chip and the substrate adhered together by the adhesive layers can be avoided.

In detail, the first adhesive layer 151 and the second adhesive layer 153 are disposed between the first circuit portion 131 and the first electrode portion 111 and between the second circuit portion 133 and the second electrode portion 113 respectively through printing, electroplating, evaporating, sputtering, chemical plating, ball mounting, bumping, or coating.

In the preferred embodiments of the present invention, the chip preferably has a size of 45 mil×45 mil, and specifically, the size of 45 mil×45 mil is mainly suitable for the high-voltage light emitting diode (LED) chip. However, the chip of the present invention is not limited to this specific size, and as will be appreciated by people skilled in the art, the length (or width) of the chip may range between 250 μm to 1500 μm. For example, the chip may have a size of 250 μm×250 μm, 250 μm×575 μm, 700 μm×700 μm, 1000 μm×1000 μm, or 1125 μm×1125 μm.

As compared with the conventional package structure, the adhesive layers in the package structure 1 of this embodiment are made of materials with negative coefficients of thermal expansion which have expand as the temperature falls and contract as the temperature rises. Specifically, when being used within a specific temperature range, the materials with negative coefficients of thermal expansion tend to contract inwards when the temperature rises gradually so that the volume thereof is reduced slightly. As a result, the pores inside the materials with negative coefficients of thermal expansion are shrunken further to result in a reduced distance between the chip 11 and the substrate 13; as a result, the shifting of the chip during the adhering process can be corrected to some extent, which further compensates for the alignment errors caused during the adhesion of the chip.

Furthermore, because the materials with negative coefficients of thermal expansion are adopted for the adhesive layer 15 in the embodiments of the present invention, the electrical contact between the first adhesive layer 151 and the second adhesive layer 152 due to excessive volume expansion can be avoided during the process of thermal expansion. As a result, the problem of electrical conduction between the first electrode portion 111, second electrode portion 113, first circuit portion 131, and second circuit portion 133 can be avoided. Thereby, the product yield of light emitting diodes packaged in a flip-chip manner is effectively improved.

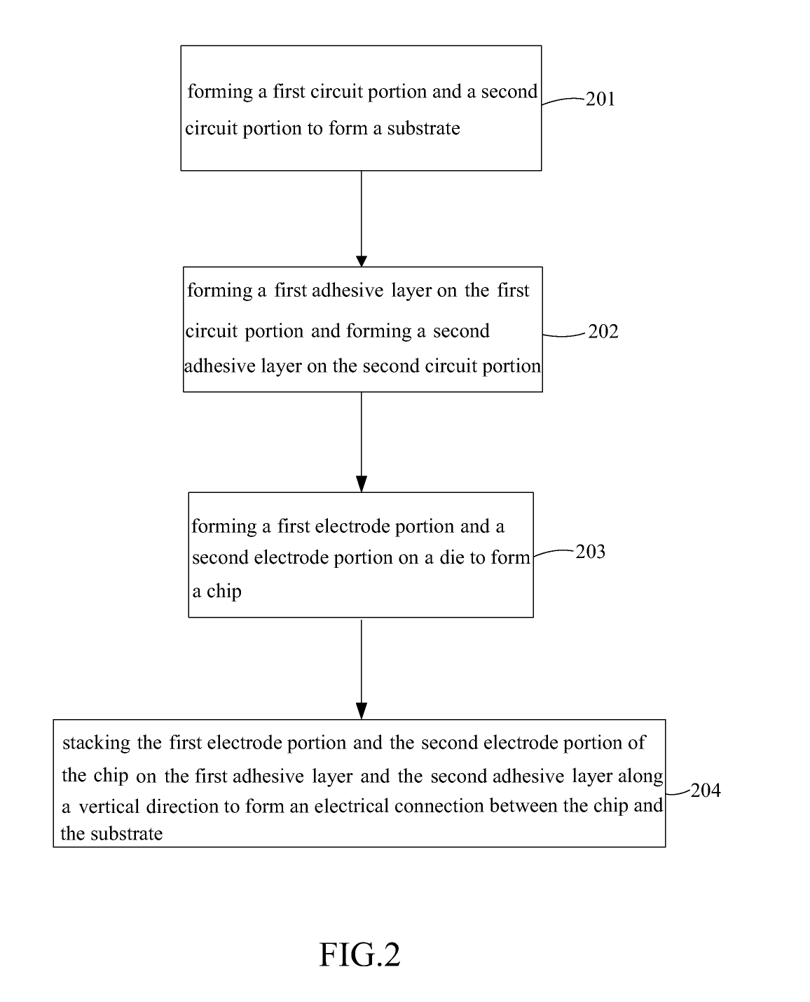

FIG. 2 illustrates a flowchart diagram of a manufacturing method for the package structure according to the embodiment of the present invention. First, as shown in step 201, the first and second circuit portions are formed to form a substrate. The first and second circuit portions are formed on an upper surface of the substrate respectively and are a part of the circuit layout on the upper surface of the substrate. Then, as shown in step 202, the first adhesive layer is formed on the first circuit portion, while the second adhesive layer is formed on the second circuit portion. The first adhesive layer and the second adhesive layer are each a material with a negative coefficient of thermal expansion (negative CTE). In detail, a working temperature of disposing the first adhesive layer and the second adhesive layer is−273 to 800. The material with the negative coefficient of thermal expansion comprises a metal compound material, while the first adhesive layer and the second adhesive layer may further have different thermal expansion coefficients. As shown in step 203, the first and second electrode portions are formed on a die to form a chip. The first electrode portion and the second electrode portion are formed on the lower surface of the chip respectively and have different areas. As shown in step 204, the chip is stacked on the upper surface of the substrate along the vertical direction. The first electrode portion of the chip is disposed perpendicular to the first adhesive layer and the first circuit portion of the substrate to form an electrical connection therebetween, while the second electrode portion of the chip is disposed perpendicular to the second adhesive layer and the second circuit portion of the substrate to form an electrical connection therebetween. Thereby, the chip can be electrically connected with the substrate. Moreover, an area of the substrate is greater than that of the chip so that the chip can be completely disposed within the area of the upper surface of the substrate. Through the aforesaid steps, the package structure shown in the aforesaid preferred embodiment (e.g., as shown in FIG. 1) can be manufactured.

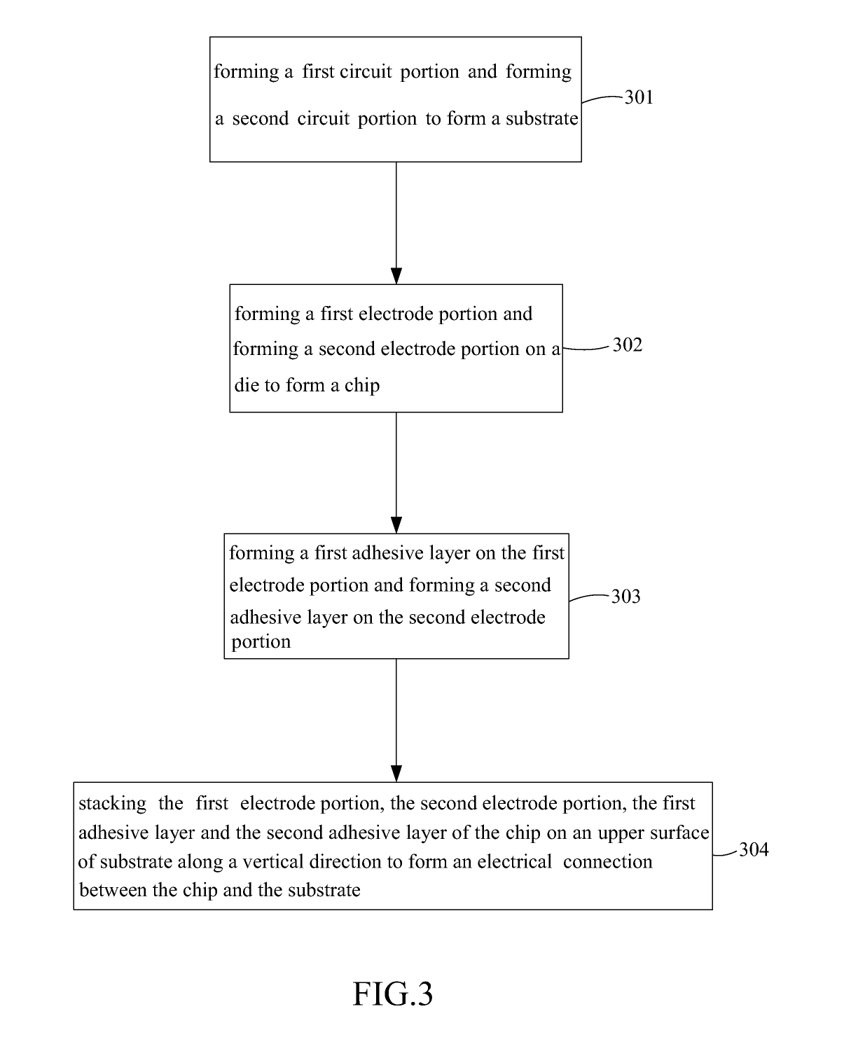

As shown in FIG. 3, there is shown another flowchart diagram of the manufacturing method for the package structure according to the embodiment of the present invention. In this manufacturing method, similarly as shown in step 301, the first circuit portion and second circuit portion are formed to form a substrate. The manufacturing method for the package structure of this embodiment differs from the aforesaid manufacturing method for the package structure as follows. First, as shown in step 302, the first and second electrode portions are formed on a die to form a chip. The first and second electrode portions are formed on the lower surface of the chip respectively. Next as shown in step 303, a first adhesive layer is formed on the first electrode portion of the chip, while a second adhesive layer is formed on the second electrode portion of the chip. The first adhesive layer and the second adhesive layer are each a material with a negative coefficient of thermal expansion (negative CTE). Then, as shown in step 304, the first electrode portion and the second electrode portion of the chip, as well as the first adhesive layer and the second adhesive layer are stacked on an upper surface of the substrate along a vertical direction. The first circuit portion is disposed perpendicular to the first adhesive layer and the first electrode portion to form an electrical connection therebetween. The second circuit portion is disposed perpendicular to the second adhesive layer and the second electrode portion to form an electrical connection therebetween. Thereby, the chip can be electrically connected with the substrate. Through the aforesaid steps, the package structure shown in the aforesaid preferred embodiment (e.g., as shown in FIG. 1) can also be manufactured.

Apart from the flow processes shown in FIG. 2 and FIG. 3, the steps of forming the substrate and the chip may also be carried out separately by people skilled in the art to shorten the time necessary for the whole manufacturing process.

In the aforesaid embodiments, the metal compound material comprises ZrW₂O₈, PbTiO₃, BaTiO₃, ZrV₂O₇, TaVO₅, LiAlSiO₄, AgI or a combination thereof. However, in other embodiments, a glass-ceramic, a resin, a ceramic or a combination thereof may also be doped into the aforesaid metal compound material for use as a material with a negative coefficient of thermal expansion.

The first adhesive layer may be disposed between the first circuit portion and the first electrode portion, while the second adhesive layer may be disposed between the second circuit portion and the second electrode portion through, for example but not limited to, printing, electroplating, evaporating, sputtering, chemical plating, ball mounting, bumping, or coating.

According to the above descriptions, materials with negative coefficients of thermal expansion are used for electrical connections between the chip and the substrate in the package structure using the manufacturing method of the embodiments of the present invention. Therefore, when the temperature changes during the adhering process, the presence of pores inside the adhesive material due to thermal expansion or contraction is avoided and the interval between the chip and the substrate is reduced. Furthermore, the alignment errors between the chip and the substrate that occur during the adhesion of the chip are further compensated to meet the needs of the art and the market.

The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. A package structure, comprising:
a chip, having at least one electrode portion;
a substrate, having at least one circuit portion ; and
at least one adhesive layer, disposed between the at least one electrode portion and the at least one circuit portion to form an electrical connection therebetween;
wherein the adhesive layer is a material with a negative coefficient of thermal expansion (Negative CTE), and the material comprises a metal compound material.

2. The package structure as claimed in claim 1, wherein a working temperature of the material with the negative coefficient of thermal expansion is−273 to 800.

3. The package structure as claimed in claim 1, wherein the at least one electrode portion has a first electrode portion and a second electrode portion, the at least one circuit portion has a first circuit portion and a second circuit portion, the at least one adhesive layer has a first adhesive layer and a second adhesive layer, the first adhesive layer and the second adhesive layer have different thermal expansion coefficients, the first adhesive layer is disposed between and electrically connected to the first electrode portion and the first circuit portion, and the second adhesive layer is disposed between and electrically connected to the second electrode portion and the second circuit portion.

4. The package structure as claimed in claim 1, wherein the metal compound material comprises ZrW₂O₈, PbTiO₃, BaTiO₃, ZrV₂O₇, TaVO₅, LiAlSiO₄ (β-eucryptite), AgI or a combination thereof.

5. The package structure as claimed in claim 1, wherein the at least one adhesive layer further comprises a glass-ceramic, a resin, a ceramic or a combination thereof.

6. The package structure as claimed in claim 1, wherein the chip is a light emitting diode chip.

7. The package structure as claimed in claim 1, wherein a length or a width of the chip is between 250 μm to 1500 μm.

8. The package structure as claimed in claim 7, wherein a size of the chip is 45 mil×45 mil.

9. A manufacturing method of a package structure, comprising:
forming at least one electrode portion on a die to form a chip;
forming at least one circuit portion on a base to form a substrate; and
disposing at least one adhesive layer between the at least one electrode portion and the at least one circuit portion to form an electrical connection between the chip and the substrate,
wherein the at least one adhesive layer is a material with a negative coefficient of thermal expansion (Negative CTE), and the material comprises a metal compound material.

10. The manufacturing method as claimed in claim 9, wherein a working temperature of disposing the at least one adhesive layer is−273 to 800.

11. The manufacturing method as claimed in claim 9, wherein the step of forming the at least one electrode portion further comprises two steps of forming a first electrode portion and forming a second electrode portion respectively, the step of forming the at least one circuit portion further comprises two steps of forming a first circuit portion and forming a second circuit portion respectively, the step of disposing the at least one adhesive layer further comprises two steps of disposing a first adhesive layer between the first electrode portion and the first circuit portion and disposing a second adhesive layer between the second electrode portion and the second circuit portion, and the first adhesive layer and the second adhesive layer have different thermal expansion coefficients.

12. The manufacturing method as claimed in claim 9, wherein the at least one adhesive layer is disposed between the at least one electrode portion and the at least one circuit portion by printing, electroplating, evaporating, sputtering, chemical plating, ball mounting, bumping, or coating.
